(19) United States
(12) Patent Application Publication
(10) Pub. No.: US 2026/0344255 A1
(43) Pub. Date: Oct. 29, 2026

(54) DISPLAY PANEL AND DISPLAY DEVICE

(71) Applicant: HEFEI VISIONOX TECHNOLOGY CO., LTD., Hefei (CN)

(72) Inventors: Jiazuo CAI, Hefei (CN); Jen-Yu LEE, Hefei (CN); Tingxia HE, Hefei (CN)

(73) Assignee: HEFEI VISIONOX TECHNOLOGY CO., LTD., Hefei (CN)

(21) Appl. No.: 19/440,008

(22) Filed: Jan. 5, 2026

Related U.S. Application Data
(63) Continuation of application No. PCT/CN2025/133144, filed on Nov. 6, 2025.

(30) Foreign Application Priority Data
Apr. 29, 2025 (CN) 202510559518.7

(51) Int. Cl. H10K 59/80; H10K 59/131; H10K 102/00

(52) U.S. Cl. CPC H10K 59/8723; H10K 59/131; H10K 59/80515; H10K 2102/351

(57) ABSTRACT

A display panel and a display device. The display panel includes: an isolation structure provided with an isolation opening, an orthographic projection of the isolation opening on the substrate including a first edge and a second edge, a length of the first edge being greater than a length of the second edge; a first electrode including a first sub-portion and a second sub-portion. In a thickness direction of the display panel, a distance between an end of the first sub-portion away from the substrate and a plane where a first surface of the isolation structure lies is a first distance, a distance between an end of the second sub-portion away from the substrate and the plane where the first surface lies is a second distance, and the first distance is greater than the second distance.

### CROSS-REFERENCE TO RELATED APPLICATION

The application is a continuation application of International Application No. PCT/CN2025/133144, filed on Nov. 6, 2025, which claims priority to Chinese patent application No. 202510559518.7 filed on Apr. 29, 2025, and titled “DISPLAY PANEL AND DISPLAY DEVICE”, all of which are hereby incorporated by reference in their entireties.

### FIELD

The application relates to the technology field of display, and in particular, to a display panel and a display device.

### BACKGROUND

In the manufacturing process of traditional display panels, patterning of light-emitting pixels is typically achieved using a Fine Metal Mask (FMM). FMM technology is mature and has extensive mass-production experience. However, FMM technology also has issues such as limited precision, high development costs, and long development cycles. Technology without fine metal masks eliminates the limitations of traditional OLED processes on display size, resolution, and other screen performance aspects, offering advantages such as high performance, global scalability, and agile delivery. Patents CN118251982A, CN116648095A, CN117062489A, CN118742138A, CN118678783A, CN118660598A, CN118675450A, CN118824188A, and CN118781966A disclose related content of display panel manufacturing technology without fine metal masks for reference.

### SUMMARY

Embodiments of the application provide a display panel and a display device. By correspondingly defining that a first distance of a first sub-portion corresponding to a first edge is greater than a second distance of a second sub-portion corresponding to a second edge, the connecting area between the first sub-portion and an isolation structure corresponding to the first edge is further increased, thereby reducing the impedance between the corresponding first sub-portion and the isolation structure corresponding to the first edge. Thus, the display effect of the display panel is improved, the incidence of dark spots or dark patches is reduced, and the reliability of the display panel is improved.

An embodiment of the application provides a display panel, including: a substrate; an isolation structure disposed on a side of the substrate, the isolation structure being provided with at least one isolation opening, an orthographic projection of the at least one isolation opening on the substrate including at least one first edge and at least one second edge, within the same isolation opening, a length of the first edge being greater than a length of the second edge; at least one light-emitting functional layer, at least a portion of the at least one light-emitting functional layer being located within the at least one isolation opening; at least one first electrode, the at least one first electrode being located on a side of the at least one light-emitting functional layer away from the substrate and connecting with the isolation structure, the at least one first electrode including at least one first sub-portion and at least one second sub-portion, the first sub-portion being a portion of the first electrode connecting with the isolation structure corresponding to the first edge, the second sub-portion being a portion of the first electrode connecting with the isolation structure corresponding to the second edge; wherein the isolation structure includes a first surface close to the substrate, within the same first electrode, and in a thickness direction of the display panel, a distance between an end of the first sub-portion away from the substrate and a plane where the first surface lies is a first distance, a distance between an end of the second sub-portion away from the substrate and the plane where the first surface lies is a second distance, and the first distance is greater than the second distance.

An embodiment of the application provides a display panel, including: a substrate; an isolation structure disposed on a side of the substrate, the isolation structure being provided with at least one isolation opening, an orthographic projection of the at least one isolation opening on the substrate including at least one first edge and at least one second edge, within the same isolation opening, a length of the first edge being greater than a length of the second edge; at least one light-emitting functional layer, at least a portion of the at least one light-emitting functional layer being located within the at least one isolation opening; at least one first electrode, the at least one first electrode being located on a side of the at least one light-emitting functional layer away from the substrate and connecting with the isolation structure, the at least one first electrode including at least one first sub-portion and at least one second sub-portion, the first sub-portion being a portion of the first electrode connecting with the isolation structure corresponding to the first edge, the second sub-portion being a portion of the first electrode connecting with the isolation structure corresponding to the second edge; wherein within the same first electrode, a unit length connecting area of the first sub-portion of the first electrode connecting with the isolation structure is a first unit length area, a unit length connecting area of the second sub-portion of the first electrode connecting with the isolation structure is a second unit length area, the first unit length area is greater than the second unit length area; wherein the first unit length area is a ratio of a total area of the first sub-portion of the first electrode connecting with the isolation structure to the length of the first edge, and the second unit length area is a ratio of a total area of the second sub-portion of the first electrode connecting with the isolation structure to the length of the second edge.

An embodiment of the application provides a display panel, including: a substrate; an isolation structure disposed on a side of the substrate, the isolation structure being provided with at least one isolation opening, an orthographic projection of the at least one isolation opening on the substrate including at least one first edge and at least one second edge, within the same isolation opening, a length of the first edge being greater than a length of the second edge; at least one light-emitting functional layer, at least a portion of the at least one light-emitting functional layer being located within the at least one isolation opening; at least one first electrode, the at least one first electrode being located on a side of the at least one light-emitting functional layer away from the substrate and connecting with the isolation structure, the at least one first electrode including at least one first sub-portion and at least one second sub-portion, the first sub-portion being a portion of the first electrode connecting with the isolation structure corresponding to the first edge, the second sub-portion being a portion of the first electrode connecting with the isolation structure corresponding to the second edge; wherein within the same first electrode, a maximum thickness of the first sub-portion is greater than a maximum thickness of the second sub-portion.

An embodiment of the application provides a display panel, including: a substrate; an isolation structure disposed on a side of the substrate, the isolation structure being provided with at least one isolation opening, an orthographic projection of the at least one isolation opening on the substrate including at least one first edge and at least one second edge, within the same isolation opening, a length of the first edge being greater than a length of the second edge; at least one light-emitting functional layer, at least a portion of the at least one light-emitting functional layer being located within the at least one isolation opening; at least one first electrode, the at least one first electrode being located on a side of the at least one light-emitting functional layer away from the substrate and connecting with the isolation structure, the at least one first electrode including at least one first sub-portion and at least one second sub-portion, the first sub-portion being a portion of the first electrode connecting with the isolation structure corresponding to the first edge, the second sub-portion being a portion of the first electrode connecting with the isolation structure corresponding to the second edge; wherein within the same first electrode, in a cross-section along a thickness direction of the display panel, a contact length between the first sub-portion of the first electrode and an inner wall surface of the isolation structure is a first contact length, a contact length between the second sub-portion of the first electrode and the inner wall surface of the isolation structure is a second contact length; wherein the first contact length is greater than the second contact length, and the inner wall surface of the isolation structure is a surface of the isolation structure facing the isolation opening.

An embodiment of the application provides a display panel, including: a substrate; an isolation structure disposed on a side of the substrate, the isolation structure being provided with at least one isolation opening, an orthographic projection of the at least one isolation opening on the substrate including at least one first edge and at least one third edge, within the same isolation opening, an extension direction of the first edge intersecting with an extension direction of the third edge, and a length of the first edge being greater than a length of the third edge; at least one light-emitting functional layer, at least a portion of the at least one light-emitting functional layer being located within the at least one isolation opening; at least one first electrode, the at least one first electrode being located on a side of the at least one light-emitting functional layer away from the substrate and connecting with the isolation structure, the at least one first electrode including at least one first sub-portion and at least one third sub-portion, the first sub-portion being a portion of the first electrode connecting with the isolation structure corresponding to the first edge, the third sub-portion being a portion of the first electrode connecting with the isolation structure corresponding to the third edge; wherein the isolation structure includes a first surface close to the substrate, within the same first electrode, and in a thickness direction of the display panel, a distance between an end of the first sub-portion away from the substrate and a plane where the first surface lies is a first distance, a distance between an end of the third sub-portion away from the substrate and the plane where the first surface lies is a third distance, and the first distance is greater than the third distance.

An embodiment of the application provides a display device, including the display panel according to any of the above aspects.

Compared with the related art, the display panel provided by the embodiments of the application includes the substrate, the isolation structure, and the at least one first electrode. At least a portion of the at least one light-emitting functional layer is located within the at least one isolation opening, so that light emitted from the at least one light-emitting functional layer can exit through the at least one isolation opening. The orthographic projection of the at least one isolation opening on the substrate includes at least one first edge and at least one second edge, and the length of the first edge is greater than the length of the second edge. This embodiment correspondingly defines that the first distance of the first sub-portion corresponding to the first edge is greater than the second distance of the second sub-portion corresponding to the second edge, thereby further increasing the connecting area between the first sub-portion and the isolation structure corresponding to the first edge, and reducing the impedance between the corresponding first sub-portion and the isolation structure corresponding to the first edge. Thus, the display effect of the display panel is improved, the incidence of dark spots or dark patches is reduced, and the reliability of the display panel is improved.

### BRIEF DESCRIPTION OF THE DRAWINGS

FIG. 1 is a schematic structural diagram of a display panel according to an embodiment of the application;

FIG. 2 is a partial enlarged view of area Q in FIG. 1 according to an embodiment of the application;

FIG. 3 is a cross-sectional view at A-A in FIG. 2 according to an embodiment of the application;

FIG. 4 is a partial enlarged view of area A in FIG. 3 according to an embodiment of the application;

FIG. 5 is a cross-sectional view at C-C in FIG. 2 according to an embodiment of the application;

FIG. 6 is another partial enlarged view of area Q in FIG. 1 according to an embodiment of the application;

FIG. 7 is a schematic structural diagram of a conductive layer according to an embodiment of the application;

FIG. 8 is another cross-sectional view at A-A in FIG. 2 according to an embodiment of the application;

FIG. 9 is yet another cross-sectional view at A-A in FIG. 2 according to an embodiment of the application;

FIG. 10 is yet another partial enlarged view of area Q in FIG. 1 according to an embodiment of the application;

FIG. 11 is a cross-sectional view at M-M in FIG. 10 according to an embodiment of the application.

### DETAILED DESCRIPTION

The features and exemplary embodiments of various aspects of the application will be described in detail below. To make the objectives, solutions, and advantages of the application more clear, the application is further described in detail below with reference to the accompanying drawings and specific embodiments. It should be understood that the specific embodiments described herein are merely configured to explain the application and are not configured to limit the application. For those skilled in the art, the application can be implemented without some of these specific details. The following description of the embodiments is merely intended to provide a better understanding of the application by illustrating examples of the application.

It should be understood that when describing the structure of a component, under a condition that one layer or region is referred to as being “on” or “above” the other layer or region, the layer or region may be directly on the other layer or region, or intervening layers or regions may be present. Moreover, if the component is flipped, the layer or region will be “below” or “under” the other layer or region.

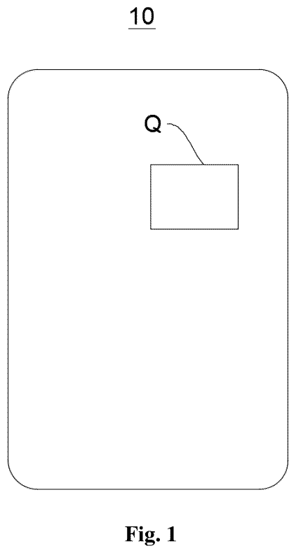

The embodiments of the application provide a display panel and a display device. The various embodiments of the display panel and the display device will be described below with reference to FIGS. 1 to 11.

Referring to FIGS. 1 to 4, a display panel 10 according to an embodiment of the application includes: a substrate 1; an isolation structure 2 disposed on a side of the substrate 1, the isolation structure 2 being provided with at least one isolation opening K, an orthographic projection of the at least one isolation opening K on the substrate 1 including at least one first edge B1 and at least one second edge B2, within the same isolation opening K, a length of the first edge B1 being greater than a length of the second edge B2; at least one light-emitting functional layer 4, at least a portion of the at least one light-emitting functional layer 4 being located within the at least one isolation opening K; at least one first electrode 3, the at least one first electrode 3 being located on a side of the at least one light-emitting functional layer 4 away from the substrate 1 and connecting with the isolation structure 2, the at least one first electrode 3 including at least one first sub-portion Z1 and at least one second sub-portion Z2, the first sub-portion Z1 being a portion of the first electrode 3 connecting with the isolation structure 2 corresponding to the first edge B1, the second sub-portion Z2 being a portion of the first electrode 3 connecting with the isolation structure 2 corresponding to the second edge B2; wherein the isolation structure 2 includes a first surface N1 close to the substrate 1, within the same first electrode 3, and in a thickness direction of the display panel 10, a distance between an end of the first sub-portion Z1 away from the substrate 1 and a plane where the first surface N1 lies is a first distance P1, a distance between an end of the second sub-portion Z2 away from the substrate 1 and the plane where the first surface N1 lies is a second distance P2, and the first distance P1 is greater than the second distance P2.

The display panel 10 provided by the embodiment of the application includes the substrate 1, the isolation structure 2, and the at least one first electrode 3. At least a portion of the at least one light-emitting functional layer 4 is located within the at least one isolation opening K, so that the light emitted from the at least one light-emitting functional layer 4 can exit through the at least one isolation opening K. The orthographic projection of the at least one isolation opening K on the substrate 1 includes the at least one first edge B1 and the at least one second edge B2, and within the same isolation opening K, the length of the first edge B1 is greater than the length of the second edge B2. This embodiment correspondingly defines that the first distance P1 of the first sub-portion Z1 corresponding to the first edge B1 is greater than the second distance P2 of the second sub-portion Z2 corresponding to the second edge B2, thereby further increasing the connecting area between the first sub-portion Z1 and the isolation structure 2 corresponding to the first edge B1, and reducing the impedance between the corresponding first sub-portion Z1 and the isolation structure 2 corresponding to the first edge B1. Thus, the display effect of the display panel 10 is improved, the incidence of dark spots or dark patches is reduced, and the reliability of the display panel 10 is improved.

Through research and experimentation, the inventors have found that under a condition that the length of the first edge B1 is greater than the length of the second edge B2, adjusting the evaporation angle can achieve the first distance P1 being greater than the second distance P2, and the corresponding display effect is superior to the condition that the first distance P1 equals the second distance P2.

In this embodiment, the first edge B1 and the second edge B2 may be two edges that are adjacent and connected, or may be two edges that are unconnected. The relative position of the first edge B1 and the second edge B2 is not particularly limited, and only the length relationship between the first edge B1 and the second edge B2 is defined.

In this embodiment, the first sub-portion Z1 may directly connect with the isolation structure 2 corresponding to the first edge B1, i.e., the first sub-portion Z1 may contact the isolation structure 2 corresponding to the first edge B1. Alternatively, the first sub-portion Z1 may indirectly connect with the isolation structure 2 corresponding to the first edge B1, i.e., other conductive layers may be provided between the first edge B1 and the isolation structure 2 as needed. Similarly, the second sub-portion Z2 may directly connect with the isolation structure 2 corresponding to the second edge B2, i.e., the second sub-portion Z2 may contact the isolation structure 2 corresponding to the second edge B2. Alternatively, the second sub-portion Z2 may indirectly connect with the isolation structure 2 corresponding to the second edge B2, i.e., other conductive layers may be provided between the second edge B2 and the isolation structure 2 as needed.

Optionally, the first sub-portion Z1 and the second sub-portion Z2 may respectively connect with the inner wall surfaces of the isolation structure 2 corresponding to the first edge B1 and the second edge B2. The inner wall surface of the isolation structure 2 is the surface of the isolation structure 2 facing the isolation opening K.

Along the thickness direction of the display panel 10, the end of the first sub-portion Z1 away from the substrate 1 is the highest point of the first sub-portion Z1 corresponding to the first edge B1. Similarly, along the thickness direction of the display panel 10, the end of the second sub-portion Z2 away from the substrate 1 is the highest point of the second sub-portion Z2 corresponding to the second edge B2. Through research and experimentation, the inventors have found that increasing the distance of the first electrode 3 from the isolation structure 2 can correspondingly increase the connecting area between the first electrode 3 and the isolation structure 2. That is, in this embodiment, by defining the first distance P1 to be greater than the second distance P2, the connecting area between the first sub-portion Z1 and the isolation structure 2 is increased, the impedance between the first sub-portion Z1 and the isolation structure 2 is improved, thereby enhancing the display effect of the display panel 10.

Optionally, the substrate 1 may include a base and an array layer. The array layer may include a drive circuit. For example, the array layer may include a first conductive layer, a second conductive layer, and a third conductive layer sequentially stacked on a side of the substrate 1. Insulating layers are provided between adjacent conductive layers. Exemplarily, a pixel drive circuit disposed on the array layer includes a transistor V and a storage capacitor. The transistor V includes an active layer W, a gate G, a source S, and a drain D. The materials of the source S and the gate G may include one or more of molybdenum, titanium, aluminum, copper, etc. The gate of the transistor V is typically used to receive a control signal to turn the transistor V on or off under the control of the control signal. One of the source S and the drain D of the transistor V is connected to a light-emitting unit to control normal light emission of the light-emitting unit.

Optionally, the light-emitting functional layer 4 includes one or more of an electron injection layer, an electron transport layer, a light-emitting material layer, a hole blocking layer, an electron blocking layer, a hole transport layer, and a hole injection layer. The specific selection can be made according to the type of the light-emitting layer and is not particularly limited.

Optionally, the material of the first electrode 3 may be a metal material such as silver (Ag), aluminum (Al), lithium (Li), magnesium (Mg), ytterbium (Yb), calcium (Ca), or indium (In), or an alloy of the aforementioned metals, such as magnesium-silver alloy (Mg/Ag), lithium-aluminum alloy (Li/Al), which is not limited in this embodiment.

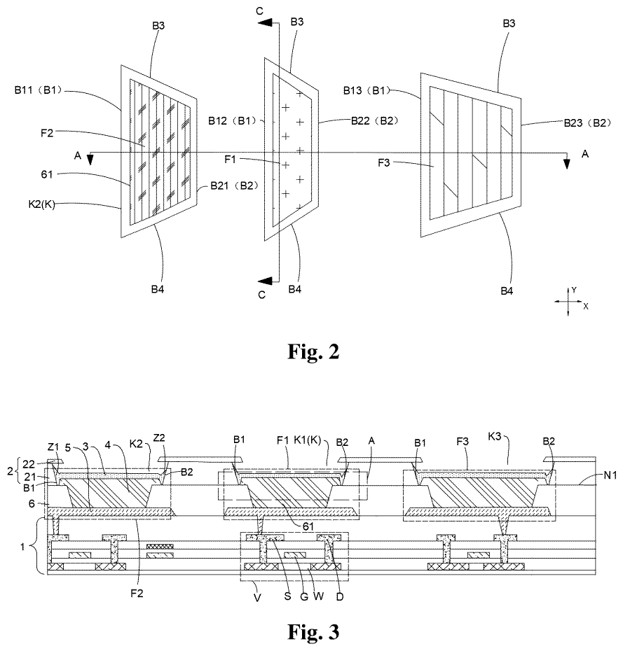

Referring to FIG. 2, in some optional embodiments, within the same isolation opening K, an angle between an extension direction of the first edge B1 and an extension direction of the second edge B2 is greater than or equal to 0° and less than or equal to 10°, so that compared to other edges (such as a third edge B3), the first edge B1 and the second edge B2 can be effective connecting edges for the first sub-portion Z1 and the second sub-portion Z2 formed by a linear evaporation source, reducing manufacturing difficulty.

Under a condition that the angle between the extension direction of the first edge B1 and the extension direction of the second edge B2 is 0°, the first edge B1 and the second edge B2 are parallel. Considering factors such as manufacturing cost and difficulty, by using the portion of the isolation structure 2 corresponding to the first edge B1 and second edge B2 that are parallel, effective connection of the first electrode 3 is achieved. Under a condition that the first edge B1 and the second edge B2 are parallel, the orthographic projection of the corresponding isolation opening K on the substrate 1 may have a shape such as a trapezoid shape or a hexagon shape.

Optionally, the extension direction of the first edge B1 and the extension direction of the second edge B2 may also be approximately parallel, or they may be arranged parallel within process error limits.

Optionally, along a direction perpendicular to the extension direction of the first edge B1, the first edge B1 and the second edge B2 are at least partially oppositely arranged, i.e., along the direction perpendicular to the extension direction of the first edge B1, the first edge B1 and the second edge B2 are arranged sequentially, to improve the regularity of the arrangement of the isolation opening K and facilitate subsequent evaporation of the first electrode 3.

Referring to FIG. 2, in some optional embodiments, the first edge B1 and the second edge B2 are both straight edges, thereby reducing manufacturing difficulty and facilitating that the distances between the ends of the first sub-portion Z1 away from the substrate 1 at different positions and the plane where the first surface N1 lies are equal everywhere, and the distances between the ends of the second sub-portion Z2 away from the substrate 1 at different positions and the plane where the first surface N1 lies are equal everywhere, i.e., facilitating the adjustment and control of the first distance P1 and the second distance P2.

Under a condition that the first edge B1 and the second edge B2 are both straight edges, the extension directions of the first edge B1 and the second edge B2 are the extension directions of the respective straight edges.

In other optional embodiments, at least one of the first edge B1 and the second edge B2 is a curved edge. At this time, since the first sub-portion Z1 and the second sub-portion Z2 are typically formed by scanning with a linear evaporation source, optionally, under a condition that the first edge B1 and the second edge B2 are both curved edges, the line connecting the highest points of the ends of the first sub-portion Z1 away from the substrate 1 at different positions is a curve, and the line connecting the highest points of the ends of the second sub-portion Z2 away from the substrate 1 at different positions is a curve. In this case, the first distance P1 may refer to the average or maximum value of the heights of the highest points of the ends of the first sub-portion Z1 away from the substrate 1 at different positions, and the second distance P2 may refer to the average or maximum value of the heights of the highest points of the ends of the second sub-portion Z2 away from the substrate 1 at different positions.

Under a condition that the first edge B1 and the second edge B2 are both curved edges, the extension direction of the first edge B1 may refer to an extension direction of the tangent at a certain point on the first edge B1, such as an extension direction of the tangent at the midpoint of the first edge B1. The extension direction of the second edge B2 may refer to an extension direction of the tangent at a certain point on the second edge B2, such as an extension direction of the tangent at the midpoint of the second edge B2.

In some optional embodiments, the first edge B1 is a longest edge among the edges of the orthographic projection of the at least one isolation opening K on the substrate 1. It can be understood that the lengths of other edges of the orthographic projection of the at least one isolation opening K on the substrate 1 are all less than the length of the first edge B1, i.e., the first distance P1 corresponding to the first sub-portion Z1 is greater than the distances of other portions of the first electrode 3 from the isolation structure 2.

Optionally, the orthographic projection of the at least one isolation opening K on the substrate 1 is a polygon, i.e., all edges of the orthographic projection of the at least one isolation opening K on the substrate 1 are straight edges, thereby facilitating manufacturing.

Optionally, the orthographic projection of the at least one isolation opening K on the substrate 1 is a hexagon or a trapezoid. The specific shape can be selected according to actual pixel arrangement requirements and is not particularly limited.

For example, under a condition that the orthographic projection of the at least one isolation opening K on the substrate 1 is a trapezoid, the first edge B1 may correspond to the base edge of the trapezoid, and the second edge B2 may correspond to the top edge or leg edge of the trapezoid. In other embodiments, the extension direction of the first edge B1 may also intersect with the extension direction of the second edge B2.

Referring to FIGS. 2, 4, and 5, in some optional embodiments, the orthographic projection of the at least one isolation opening K on the substrate 1 further includes at least one third edge B3, an extension direction of the first edge B1 intersects with an extension direction of the third edge B3, and a length of the third edge B3 is less than the length of the first edge B1; the at least one first electrode 3 further includes at least one third sub-portion Z3, the third sub-portion Z3 is a portion of the first electrode 3 connecting with the isolation structure 2 corresponding to the third edge B3; in the thickness direction of the display panel 10, a distance between an end of the third sub-portion Z3 away from the substrate 1 and the plane where the first surface N1 lies is a third distance P3, and the first distance P1 is greater than the third distance P3.

In this embodiment, the orthographic projection of the at least one isolation opening K on the substrate 1 includes the at least one first edge B1, the at least one second edge B2, and the at least one third edge B3. The three edges may be connected in sequence or in other connection orders, which is not particularly limited. Since the length of the third edge B3 is less than the length of the first edge B1, i.e., the third edge B3 is also a short edge relative to the first edge B1, the first distance P1 can be defined to be greater than the third distance P3, so as to increase the connecting area between the first sub-portion Z1 and the isolation structure 2 corresponding to the first edge B1, reduce the impedance between the corresponding first sub-portion Z1 and the isolation structure 2 corresponding to the first edge B1, and improve the display effect of the display panel 10.

In some optional embodiments, within the same first electrode 3, in a cross-section along the thickness direction of the display panel 10, a contact length between the first sub-portion Z1 of the first electrode 3 and an inner wall surface of the isolation structure 2 is a first contact length J1, a contact length between the third sub-portion Z3 of the first electrode 3 and the inner wall surface of the isolation structure 2 is a third contact length J3; wherein the first contact length J1 is greater than the third contact length J3, and the inner wall surface of the isolation structure 2 is a surface of the isolation structure 2 facing the isolation opening K.

The cross-section along the thickness direction of the display panel 10 may include a first plane and a third plane. Optionally, the first plane is perpendicular to the extension direction of the first edge B1, and the third plane is perpendicular to the extension direction of the third edge B3. The first contact length J1 is the contact length between the first sub-portion Z1 of the first electrode 3 and the inner wall surface of the isolation structure 2 on the first plane, and the third contact length J3 is the contact length between the third sub-portion Z3 of the first electrode 3 and the inner wall surface of the isolation structure 2 on the third plane.

Through research and experimentation, the inventors have found that the first contact length J1 being greater than the third contact length J3 indicates that the connecting effect between the first sub-portion Z1 and the inner wall surface of the isolation structure 2 is better than the connecting effect between the third sub-portion Z3 and the inner wall surface of the isolation structure 2.

In some optional embodiments, within the same first electrode 3, a unit length connecting area of the first sub-portion Z1 of the first electrode 3 connecting with the isolation structure 2 is a first unit length area, a unit length connecting area of the third sub-portion Z3 of the first electrode 3 connecting with the isolation structure 2 is a third unit length area, and the first unit length area is greater than the third unit length area; wherein the first unit length area is a ratio of a total area of the first sub-portion Z1 of the first electrode 3 connecting with the isolation structure 2 to the length of the first edge B1, and the third unit length area is a ratio of a total area of the third sub-portion Z3 of the first electrode 3 connecting with the isolation structure 2 to the length of the third edge B3.

Considering that the lengths of the first edge B1 and the third edge B3 are different, in this embodiment, the unit length connecting area of the first sub-portion Z1 of the first electrode 3 connecting with the inner wall surface of the isolation structure 2 is compared with the unit length connecting area of the third sub-portion Z3 of the first electrode 3 connecting with the inner wall surface of the isolation structure 2, so as to accurately determine the connecting effect. The first unit length area being greater than the third unit length area indicates that the connecting effect of the first sub-portion Z1 on the inner wall surface of the isolation structure 2 corresponding to the first edge B1 is better, which can reduce the impedance between the first electrode 3 and the isolation structure 2, thereby improving the performance of the display panel 10.

Optionally, the length of the third edge B3 is less than the length of the second edge B2.

Optionally, the third distance P3 is less than the second distance P2. Under a condition that the first edge B1 and the second edge B2 are parallel, the first edge B1 and the second edge B2 can be effective connecting edges for the first sub-portion Z1 and the second sub-portion Z2 formed by a linear evaporation source. Since the length of the third edge B3 is less than the lengths of the second edge B2 and the first edge B1, its impact on the connecting effect is limited. By setting the third distance P3 less than the second distance P2, the connecting area of the first sub-portion Z1 can be maximized, sacrificing the connecting effect of other edges to achieve overall maximization of the cathode connecting effect, thereby improving the display effect of the display panel.

Optionally, within the same first electrode 3, in a cross-section along the thickness direction of the display panel 10, a contact length between the second sub-portion Z2 of the first electrode 3 and the inner wall surface of the isolation structure 2 is a second contact length J2, a contact length between the third sub-portion Z3 of the first electrode 3 and the inner wall surface of the isolation structure 2 is a third contact length J3.

Through research and experimentation, the inventors have found that the second contact length J2 being greater than the third contact length J3 indicates that the connecting effect between the second sub-portion Z2 and the inner wall surface of the isolation structure 2 is better than the connecting effect between the third sub-portion Z3 and the inner wall surface of the isolation structure 2.

In some optional embodiments, within the same first electrode 3, a unit length connecting area of the second sub-portion Z2 of the first electrode 3 connecting with the isolation structure 2 is a second unit length area, a unit length connecting area of the third sub-portion Z3 of the first electrode 3 connecting with the isolation structure 2 is a third unit length area, and the second unit length area is greater than the third unit length area; wherein the second unit length area is a ratio of a total area of the second sub-portion Z2 of the first electrode 3 connecting with the isolation structure 2 to the length of the second edge B2, and the third unit length area is a ratio of a total area of the third sub-portion Z3 of the first electrode 3 connecting with the isolation structure 2 to the length of the third edge B3.

The second unit length area being greater than the third unit length area indicates that the connecting effect of the second sub-portion Z2 on the inner wall surface of the isolation structure 2 corresponding to the second edge B2 is better, which can reduce the impedance between the first electrode 3 and the isolation structure 2, thereby improving the performance of the display panel 10.

Referring to FIGS. 2, 4, and 5, in some optional embodiments, within the same isolation opening K, the first edge B1 and the second edge B2 are opposite and parallel to each other; the orthographic projection of the at least one isolation opening K on the substrate 1 further includes at least one fourth edge B4, a length of the fourth edge B4 is less than the length of the first edge B1, the fourth edge B4 and the third edge B3 are oppositely arranged, and an extension direction of the fourth edge B4 intersects with the extension direction of the third edge B3; the at least one first electrode 3 further includes at least one fourth sub-portion Z4, the fourth sub-portion Z4 is a portion of the first electrode 3 connecting with the isolation structure 2 corresponding to the fourth edge B4; in the thickness direction of the display panel 10, a distance between an end of the fourth sub-portion Z4 away from the substrate 1 and the plane where the first surface N1 lies is a fourth distance P4, and the first distance P1 is greater than the fourth distance P4.

In this embodiment, the first edge B1, the second edge B2, the third edge B3, and the fourth edge B4 may form a trapezoid. The first edge B1 and the second edge B2 respectively correspond to either the base edge or the top edge of the trapezoid, and the third edge B3 and the fourth edge B4 correspond to the two leg edges of the trapezoid.

Since the length of the fourth edge B4 is less than the length of the first edge B1, in this embodiment, the first distance P1 can be defined to be greater than the fourth distance P4, so that the connecting area between the first sub-portion Z1 and the isolation structure 2 corresponding to the first edge B1 is larger, thereby reducing the impedance between the corresponding first sub-portion Z1 and the isolation structure 2 corresponding to the first edge B1, and improving the display effect of the display panel 10.

Optionally, the length of the fourth edge B4 is less than the length of the second edge B2;

Optionally, the fourth distance P4 is less than the second distance P2, so that the connecting area between the second sub-portion Z2 and the isolation structure 2 corresponding to the second edge B2 is larger, thereby reducing the impedance between the corresponding second sub-portion Z2 and the isolation structure 2 corresponding to the second edge B2, and improving the display effect of the display panel 10.

Optionally, within the same first electrode 3, in a cross-section along the thickness direction of the display panel 10, a contact length between the second sub-portion Z2 of the first electrode 3 and the inner wall surface of the isolation structure 2 is a second contact length J2, a contact length between the fourth sub-portion Z4 of the first electrode 3 and the inner wall surface of the isolation structure 2 is a fourth contact length J4.

Through research and experimentation, the inventors have found that the second contact length J2 being greater than the fourth contact length J4 indicates that the connecting effect between the second sub-portion Z2 and the inner wall surface of the isolation structure 2 is better than the connecting effect between the fourth sub-portion Z4 and the inner wall surface of the isolation structure 2.

In some optional embodiments, within the same first electrode 3, a unit length connecting area of the second sub-portion Z2 of the first electrode 3 connecting with the isolation structure 2 is a second unit length area, a unit length connecting area of the fourth sub-portion Z4 of the first electrode 3 connecting with the isolation structure 2 is a fourth unit length area, and the second unit length area is greater than the fourth unit length area; wherein the second unit length area is a ratio of a total area of the second sub-portion Z2 of the first electrode 3 connecting with the isolation structure 2 to the length of the second edge B2, and the fourth unit length area is a ratio of a total area of the fourth sub-portion Z4 of the first electrode 3 connecting with the isolation structure 2 to the length of the fourth edge B4.

The second unit length area being greater than the fourth unit length area indicates that the connecting effect of the second sub-portion Z2 on the inner wall surface of the isolation structure 2 corresponding to the second edge B2 is better, which can reduce the impedance between the first electrode 3 and the isolation structure 2, thereby improving the performance of the display panel 10.

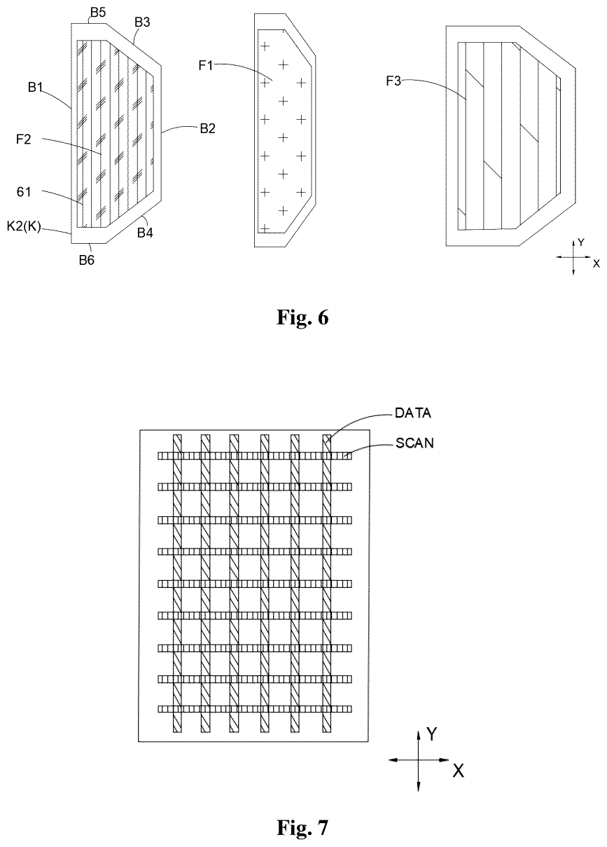

Referring to FIG. 6, optionally, the orthographic projection of the at least one isolation opening K on the substrate 1 further includes a fifth edge B5 and a sixth edge B6. The fifth edge B5 connects the first edge B1 and the third edge B3, and the sixth edge B6 connects the second edge B2 and the fourth edge B4. Correspondingly, the orthographic projection of the at least one isolation opening K on the substrate 1 is a hexagon.

Referring to FIG. 7, in some optional embodiments, the display panel 10 further includes a conductive layer disposed between the substrate 1 and the isolation structure 2; the conductive layer includes a data signal line DATA extending along a first direction Y, and the extension direction of the at least one first edge B1 is parallel to the first direction Y.

When manufacturing the first electrode 3, to ensure evaporation accuracy, the linear evaporation source used may extend along the first direction Y and move along a direction perpendicular to the first direction Y, so that the evaporation material is uniformly formed on the isolation structure 2 corresponding to the first edge B1, thereby ensuring that the first distance P1 and the second distance P2 meet the requirements.

Optionally, the extension direction of the second edge B2 is parallel to the first direction Y.

Optionally, the display panel 10 further includes a scan signal line SCAN disposed in a different layer from the data signal line DATA. Optionally, the scan signal line SCAN extends along a second direction X.

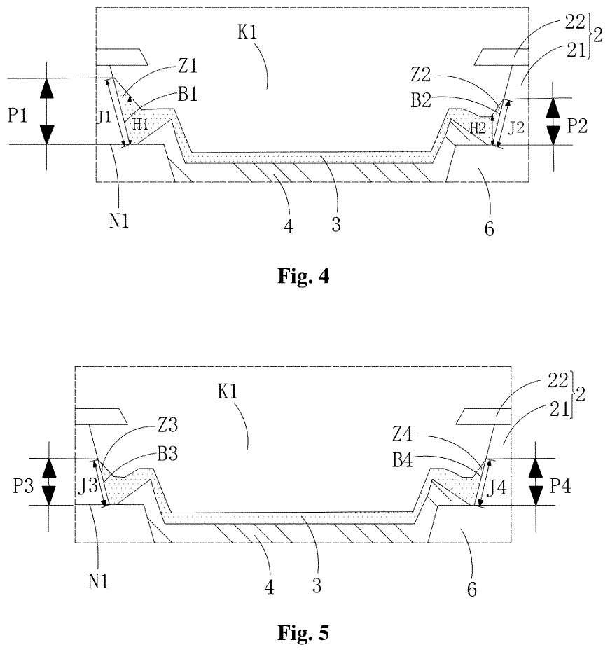

Referring to FIG. 4, in some optional embodiments, within the same first electrode 3, a maximum thickness H1 of the first sub-portion Z1 is greater than a maximum thickness H2 of the second sub-portion Z2.

In this embodiment, the maximum thickness H1 of the first sub-portion Z1 and the maximum thickness H2 of the second sub-portion Z2 may refer to the maximum thicknesses of the first sub-portion Z1 and the second sub-portion Z2 along their respective extension directions. Alternatively, exemplarily, the maximum thickness H1 of the first sub-portion Z1 and the maximum thickness H2 of the second sub-portion Z2 may be the maximum thicknesses of the first sub-portion Z1 and the second sub-portion Z2 in the thickness direction of the display panel, as shown in FIG. 4, or may be the maximum thicknesses of the first sub-portion Z1 and the second sub-portion Z2 in a direction perpendicular to the inner wall surface of the isolation structure 2 connecting the first sub-portion Z1 and the second sub-portion Z2.

By increasing the maximum thickness H1 of the first sub-portion Z1, the resistance of the first sub-portion Z1 can be further reduced, the connecting impedance between the first sub-portion Z1 and the isolation structure 2 can be improved, and the first distance P1 can be correspondingly increased, allowing the connecting area of the first sub-portion Z1 to be maximized, sacrificing the connecting effect of other edges to achieve overall maximization of the cathode connecting effect, and improving the display effect of the display panel.

Alternatively, within the same first electrode 3, an average thickness of the first sub-portion Z1 is greater than an average thickness of the second sub-portion Z2.

Considering factors such as evaporation material properties, formation position, and manufacturing process, the thickness of the first sub-portion Z1 along a direction perpendicular to its extension direction varies at different positions. Through research and experimentation, the inventors have found that by adjusting the manufacturing process to cause the average thickness of the first sub-portion Z1 being greater than the average thickness of the second sub-portion Z2, the resistance of the first sub-portion Z1 can be further reduced, the connecting impedance between the first sub-portion Z1 and the isolation structure 2 can be improved, and the first distance P1 corresponding to the first sub-portion Z1 can be correspondingly increased, thereby increasing the connecting area and improving the impedance.

In this embodiment, the average thickness of the first sub-portion Z1 and the average thickness of the second sub-portion Z2 may refer to the average thicknesses of the first sub-portion Z1 and the second sub-portion Z2 along a direction perpendicular to their respective extension directions. Alternatively, the average thickness of the first sub-portion Z1 and the average thickness of the second sub-portion Z2 may be the average thicknesses of the first sub-portion Z1 and the second sub-portion Z2 in the thickness direction of the display panel, or may be the average thicknesses of the first sub-portion Z1 and the second sub-portion Z2 in a direction perpendicular to the inner wall surface of the isolation structure 2 connecting the first sub-portion Z1 and the second sub-portion Z2.

In actual manufacturing of the first electrode 3, since the first sub-portion Z1 and the second sub-portion Z2 are located at the edges of the first electrode 3 close to the isolation structure 2, they are blocked by the isolation structure 2, so that the thicknesses of the first sub-portion Z1 and the second sub-portion Z2 are both less than the thickness of the first electrode 3 not blocked by the isolation structure 2. Through research and experimentation, the inventors have found that by adjusting the manufacturing process to cause the thickness of the first sub-portion Z1 along a direction perpendicular to its extension direction being greater than the thickness of the second sub-portion Z2 along a direction perpendicular to its extension direction, the resistance of the first sub-portion Z1 can be further reduced, the connecting impedance between the first sub-portion Z1 and the isolation structure 2 can be improved, and the connecting area can be increased, thereby improving the impedance. In some optional embodiments, within the same first electrode 3, in a cross-section along the thickness direction of the display panel 10, a contact length between the first sub-portion Z1 of the first electrode 3 and the inner wall surface of the isolation structure 2 is a first contact length J1, a contact length between the second sub-portion Z2 of the first electrode 3 and the inner wall surface of the isolation structure 2 is a second contact length J2; wherein the first contact length J1 is greater than the second contact length J2, and the inner wall surface of the isolation structure 2 is a surface of the isolation structure 2 facing the isolation opening K.

The cross-section along the thickness direction of the display panel 10 may include a first plane and a second plane. Optionally, the first plane is perpendicular to the extension direction of the first edge B1, and the second plane is perpendicular to the extension direction of the second edge B2. The first contact length J1 is the contact length between the first sub-portion Z1 of the first electrode 3 and the inner wall surface of the isolation structure 2 on the first plane, and the second contact length J2 is the contact length between the second sub-portion Z2 of the first electrode 3 and the inner wall surface of the isolation structure 2 on the second plane.

Through research and experimentation, the inventors have found that the first contact length J1 being greater than the second contact length J2 indicates that the connecting effect between the first sub-portion Z1 and the inner wall surface of the isolation structure 2 is better than the connecting effect between the second sub-portion Z2 and the inner wall surface of the isolation structure 2.

In some optional embodiments, within the same first electrode 3, a unit length connecting area of the first sub-portion Z1 of the first electrode 3 connecting with the isolation structure 2 is a first unit length area, a unit length connecting area of the second sub-portion Z2 of the first electrode 3 connecting with the isolation structure 2 is a second unit length area, and the first unit length area is greater than the second unit length area; wherein the first unit length area is a ratio of a total area of the first sub-portion Z1 of the first electrode 3 connecting with the isolation structure 2 to the length of the first edge B1, and the second unit length area is a ratio of a total area of the second sub-portion Z2 of the first electrode 3 connecting with the isolation structure 2 to the length of the second edge B2.

Considering that the lengths of the first edge B1 and the second edge B2 are different, in this embodiment, the unit length connecting area of the first sub-portion Z1 of the first electrode 3 connecting with the inner wall surface of the isolation structure 2 is compared with the unit length connecting area of the second sub-portion Z2 of the first electrode 3 connecting with the inner wall surface of the isolation structure 2, so as to accurately determine the connecting effect. The first unit length area being greater than the second unit length area indicates that the connecting effect of the first sub-portion Z1 on the inner wall surface of the isolation structure 2 corresponding to the first edge B1 is better, which can reduce the impedance between the first electrode 3 and the isolation structure 2, thereby improving the performance of the display panel 10.

Referring to FIG. 3, in some optional embodiments, in a direction away from the substrate 1, the isolation structure 2 includes a first sub-layer 21 and a second sub-layer 22 stacked sequentially, an orthographic projection of the first sub-layer 21 on the substrate 1 is located within an orthographic projection of the second sub-layer 22 on the substrate 1; the at least one first sub-portion Z1 of the at least one first electrode 3 at least connects with the first sub-layer 21.

In this embodiment, the isolation structure 2 may include two parts: the first sub-layer 21 and the second sub-layer 22. The orthographic projection of the first sub-layer 21 on the substrate 1 is located within the orthographic projection of the second sub-layer 22 on the substrate 1, i.e., the area of the orthographic projection of the first sub-layer 21 on the substrate 1 is less than or equal to the area of the orthographic projection of the second sub-layer 22 on the substrate 1. For example, under a condition that the area of the orthographic projection of the first sub-layer 21 on the substrate 1 is less than the area of the orthographic projection of the second sub-layer 22 on the substrate 1, the cross-section of the first sub-layer 21 and the second sub-layer 22 along a direction perpendicular to the plane where the substrate 1 lies may have a shape similar to “T”, so as to use the isolation structure 2 to achieve the patterned light-emitting functional layer 4 and first electrode 3.

The at least one first sub-portion Z1 of the at least one first electrode 3 at least connects with the first sub-layer 21 to achieve signal transmission.

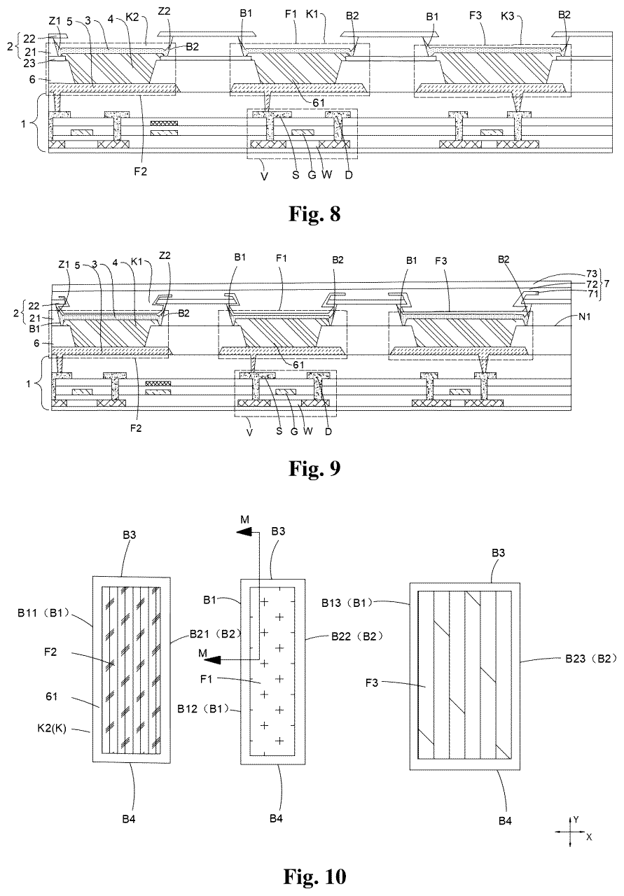

Referring to FIG. 8, in some optional embodiments, the isolation structure 2 further includes a third sub-layer 23 located on a side of the first sub-layer 21 away from the second sub-layer 22, an orthographic projection of the third sub-layer 23 on the substrate 1 is located within the orthographic projection of the second sub-layer 22 on the substrate 1.

In this embodiment, the isolation structure 2 includes three parts: the first sub-layer 21, the second sub-layer 22, and the third sub-layer 23. The orthographic projection of the third sub-layer 23 on the substrate 1 being located within the orthographic projection of the second sub-layer 22 on the substrate 1 means that the area of the orthographic projection of the second sub-layer 22 on the substrate 1 is greater than or equal to the area of the orthographic projection of the third sub-layer 23 on the substrate 1. For example, along a direction perpendicular to the plane where the substrate 1 lies, the cross-section of the first sub-layer 21, the second sub-layer 22, and the third sub-layer 23 may form a shape similar to “ [symbol] ”, so as to use the isolation structure 2 to achieve the patterned light-emitting functional layer. Specifically, when evaporating the light-emitting material, the light-emitting material may break near the isolation structure 2 to form mutually independent light-emitting units, thereby omitting the fine metal mask evaporation process, and simplifying the manufacturing process of the display panel 10.

Optionally, the first sub-layer 21, the second sub-layer 22, and the third sub-layer 23 all include conductive materials. For example, the first sub-layer 21 includes aluminum material, the second sub-layer 22 includes titanium material, and the third sub-layer 23 includes molybdenum material.

Referring to FIG. 3, in some optional embodiments, the at least one light-emitting functional layer 4 includes a plurality of light-emitting functional layers 4, the plurality of light-emitting functional layers 4 include a first light-emitting unit F1, a second light-emitting unit F2, and a third light-emitting unit F3, the first light-emitting unit F1 is configured to emit light of a first color, the second light-emitting unit F2 is configured to emit light of a second color, and the third light-emitting unit F3 is configured to emit light of a third color; the at least one isolation opening K includes a plurality of isolation openings K, the plurality of isolation openings K include a first isolation opening K1, a second isolation opening K2, and a third isolation opening K3, at least a portion of the first light-emitting unit F1 is located within the first isolation opening K1, at least a portion of the second light-emitting unit F2 is located within the second isolation opening K2, and at least a portion of the third light-emitting unit F3 is located within the third isolation opening K3.

In this embodiment, the shapes of the orthographic projections of the first isolation opening K1, the second isolation opening K2, and the third isolation opening K3 on the substrate 1 may be the same or different, and can be selected according to the arrangement of the first light-emitting unit F1, the second light-emitting unit F2, and the third light-emitting unit F3. Different shapes can be adopted according to actual needs, thereby increasing the application scenarios of the display panel 10.

Optionally, an area of an orthographic projection of the first isolation opening K1 on the substrate 1 is less than an area of an orthographic projection of the second isolation opening K2 on the substrate 1, and the area of the orthographic projection of the first isolation opening K1 on the substrate 1 is less than an area of an orthographic projection of the third isolation opening K3 on the substrate 1; the orthographic projection of the first isolation opening K1 on the substrate 1 includes the first edge B1 and the second edge B2.

That is, the orthographic projection of the first isolation opening K1 on the substrate 1 with the smallest area includes the first edge B1 and the second edge B2. The corresponding first light-emitting unit F1 emitting light of the first color also has the smallest light-emitting area. Through research, the inventors have found that light-emitting units with smaller light-emitting areas are more sensitive to connection defects. Therefore, in the embodiment of the application, the orthographic projection of the first isolation opening K1 corresponding to the first light-emitting unit F1 with the smallest light-emitting area on the substrate 1 includes the first edge B1 and the second edge B2, so as to ensure the connecting effect of the portion of the first electrode 3 corresponding to the first light-emitting unit F1, and improve the display effect.

Of course, according to actual needs, the orthographic projections of the first isolation opening K1, the second isolation opening K2, and the third isolation opening K3 on the substrate 1 may all include the first edge B1 and the second edge B2, so as to improve the light-emitting effect of the light-emitting units.

As shown in FIG. 2, the first edge B1 may include a first edge B11 of the orthographic projection of the first isolation opening K1 on the substrate 1, a first edge B12 of the orthographic projection of the second isolation opening K2 on the substrate 1, and a first edge B13 of the orthographic projection of the third isolation opening K3 on the substrate 1. The second edge B2 may include a second edge B21 of the orthographic projection of the first isolation opening K1 on the substrate 1, a second edge B22 of the orthographic projection of the second isolation opening K2 on the substrate 1, and a second edge B23 of the orthographic projection of the third isolation opening K3 on the substrate 1.

Optionally, the first edge B1 of the first isolation opening K1, the first edge B1 of the second isolation opening K2, and the first edge B1 of the third isolation opening K3 are mutually parallel to each other, so that evaporation of the first sub-portions Z1 corresponding to the first edge B1 of the first isolation opening K1, the first edge B1 of the second isolation opening K2, and the first edge B1 of the third isolation opening K3 can be achieved without adjusting the relative angle between the evaporation source and the display panel 10, thereby simplifying the process and reducing manufacturing difficulty.

In some optional embodiments, a length of the first edge B1 of the first isolation opening K1, a length of the first edge B1 of the second isolation opening K2, and a length of the first edge B1 of the third isolation opening K3 are all equal, thereby facilitating manufacturing without adjusting equipment, and simplifying the process.

Optionally, the at least one first sub-portion Z1 includes a plurality of first sub-portions Z1, the plurality of first sub-portions Z1 include a first sub-portion Z1 located within the first isolation opening K1, a first sub-portion Z1 located within the second isolation opening K2, and a first sub-portion Z1 located within the third isolation opening K3, and the first distance P1 of the first sub-portion Z1 located within the first isolation opening K1, the first distance P1 of the first sub-portion Z1 located within the second isolation opening K2, and the first distance P1 of the first sub-portion Z1 located within the third isolation opening K3 are all equal.

Because that the first distance P1 of the first sub-portion Z1 located within the first isolation opening K1, the first distance P1 of the first sub-portion Z1 located within the second isolation opening K2, and the first distance P1 of the first sub-portion Z1 located within the third isolation opening K3 are all equal, when using the evaporation equipment to form the first sub-portion Z1 located within the first isolation opening K1, the first sub-portion Z1 located within the second isolation opening K2, and the first sub-portion Z1 located within the third isolation opening K3, it is not necessary to adjust the equipment, for example, the evaporation angle, to correspondingly form each first sub-portion Z1, thereby simplifying the process, ensuring the best connecting effect, and ensuring that the thickness of the first electrode 3 corresponding to each light-emitting unit meets the requirement for effective light emission of the display panel 10.

Optionally, the at least one second sub-portion Z2 includes a plurality of second sub-portions Z2, the plurality of second sub-portions Z2 include a second sub-portion Z2 located within the first isolation opening K1, a second sub-portion Z2 located within the second isolation opening K2, and a second sub-portion Z2 located within the third isolation opening K3. Correspondingly, the second distance P2 of the second sub-portion Z2 in each isolation opening K is less than the first distance P1 of the first sub-portion Z1 in that isolation opening K, so as to improve the connecting effect of the first sub-portion Z1 on the inner wall surface of the isolation structure 2 corresponding to the first edge B1, reduce the impedance between the first electrode 3 and the isolation structure 2, and improve the performance of the display panel 10.

Referring to FIG. 3, in some optional embodiments, the display panel 10 further includes: a pixel definition layer 6 disposed on a side of the isolation structure 2 close to the substrate 1, the pixel definition layer 6 being provided with at least one pixel opening 61, an orthographic projection of the at least one pixel opening 61 on the substrate 1 being located within the orthographic projection of the at least one isolation opening K on the substrate 1, and at least a portion of the at least one light-emitting functional layer 4 being located within the at least one pixel opening 61.

Optionally, the orthographic projection of the at least one pixel opening 61 on the substrate 1 has the same shape as the orthographic projection of the at least one isolation opening K on the substrate 1.

Optionally, an edge of the pixel opening 61 coincides with an edge of the effective light-emitting region of the light-emitting unit, i.e., the edge of the pixel opening 61 coincides with the edge of the sub-pixel described below.

Optionally, a centroid of the orthographic projection of the at least one pixel opening 61 on the substrate 1 coincides with a centroid of the orthographic projection of the at least one isolation opening K on the substrate 1, i.e., the orthographic projection of the at least one pixel opening 61 on the substrate 1 and the orthographic projection of the at least one isolation opening K on the substrate 1 may have similar shapes. Their shapes may be similar, both being trapezoidal, hexagonal, etc., but the lengths are in a certain ratio to improve light extraction efficiency.

Specifically, the orthographic projection of the at least one pixel opening 61 on the substrate 1 and the orthographic projection of the at least one isolation opening K on the substrate 1 have the same shape, and the edge of the orthographic projection of the at least one pixel opening 61 on the substrate 1 is conformal with the edge of the orthographic projection of the at least one isolation opening K on the substrate 1, i.e., the edge of the orthographic projection of the at least one pixel opening 61 on the substrate 1 is parallel to the corresponding edge of the orthographic projection of the at least one isolation opening K on the substrate 1, so as to ensure that the light emitted from the pixel opening 61 is not blocked by the isolation structure 2, thereby improving light extraction efficiency.

Referring to FIG. 9, in some optional embodiments, the display panel 10 further includes an encapsulation layer 7; wherein the encapsulation layer 7 includes a first encapsulation layer 71, the first encapsulation layer 71 includes a plurality of first encapsulation units spaced apart from each other, the first encapsulation unit is located on a side of the first electrode 3 away from the substrate 1, and at least a portion of the first encapsulation unit further covers a sidewall of the isolation structure 2 facing the isolation opening K and extends to a side of the isolation structure 2 away from the substrate 1.

The first encapsulation unit is used to encapsulate the isolation opening K, reducing oxidation and erosion of devices within the isolation opening K by external moisture, thereby improving the lifespan of the display panel 10.

Optionally, the material of the first encapsulation layer 71 includes an inorganic material. That is, the first encapsulation layer 71 is an inorganic encapsulation layer. The inorganic encapsulation layer can be prepared by chemical vapor deposition, which can improve the density of the first encapsulation layer 71, thereby improving the encapsulation effect of the encapsulation layer 7.

Optionally, the encapsulation layer 7 further includes a second encapsulation layer 72, the second encapsulation layer 72 is located on a side of the first encapsulation layer 71 away from the substrate 1, and the material of the second encapsulation layer 72 includes an organic material. That is, the second encapsulation layer 72 is an organic encapsulation layer. The organic encapsulation layer can be prepared by inkjet printing, thereby allowing the encapsulation layer 7 to have a suitable thickness.

Optionally, the encapsulation layer 7 further includes a third encapsulation layer 73 located on a side of the second encapsulation layer 72 away from the substrate 1, and the material of the third encapsulation layer 73 includes an inorganic material. That is, the third encapsulation layer 73 is an inorganic encapsulation layer. Adding an inorganic encapsulation layer outside the organic encapsulation layer can further improve the encapsulation effect of the encapsulation layer 7.

Optionally, the material of the third encapsulation layer 73 is the same as the material of the first encapsulation layer 71. This allows the first encapsulation layer 71 and the third encapsulation layer 73 to be prepared using the same equipment, simplifying the manufacturing process of the display panel 10.

Optionally, the display panel 10 further includes a second electrode 5 located on a side of the light-emitting functional layer 4 facing the substrate 1; an orthographic projection of the second electrode 5 on the substrate 1 at least partially overlaps with the orthographic projection of the isolation opening K on the substrate 1.

The material of the second electrode 5 is generally a material with a high work function to improve hole injection efficiency, such as gold (Au), platinum (Pt), titanium (Ti), silver (Ag), indium tin oxide (ITO), indium zinc oxide (IZO), or transparent conductive polymers (such as polyaniline). For example, the first electrode 3 layer may be made of ITO-Ag-ITO composite material, which is not particularly limited.

Referring to FIGS. 1 to 4, another embodiment of the application further provides a display panel 10, including: a substrate 1; an isolation structure 2 disposed on a side of the substrate 1, the isolation structure 2 being provided with at least one isolation opening K, an orthographic projection of the at least one isolation opening K on the substrate 1 including at least one first edge B1 and at least one second edge B2, a length of the first edge B1 being greater than a length of the second edge B2; at least one light-emitting functional layer 4, at least a portion of the at least one light-emitting functional layer 4 being located within the at least one isolation opening K; at least one first electrode 3, the at least one first electrode 3 being located on a side of the at least one light-emitting functional layer 4 away from the substrate 1 and connecting with the isolation structure 2, the at least one first electrode 3 including at least one first sub-portion Z1 and at least one second sub-portion Z2, the first sub-portion Z1 being a portion of the first electrode 3 connecting with the isolation structure 2 corresponding to the first edge B1, the second sub-portion Z2 being a portion of the first electrode 3 connecting with the isolation structure 2 corresponding to the second edge B2; wherein within the same first electrode 3, a unit length connecting area of the first sub-portion Z1 of the first electrode 3 connecting with the isolation structure 2 is a first unit length area, a unit length connecting area of the second sub-portion Z2 of the first electrode 3 connecting with the isolation structure 2 is a second unit length area, the first unit length area is greater than the second unit length area; wherein the first unit length area is a ratio of a total area of the first sub-portion Z1 of the first electrode 3 connecting with the isolation structure 2 to the length of the first edge B1, and the second unit length area is a ratio of a total area of the second sub-portion Z2 of the first electrode 3 connecting with the isolation structure 2 to the length of the second edge B2.

The display panel 10 provided by the embodiment of the application includes the substrate 1, the isolation structure 2, and the at least one first electrode 3. At least a portion of the at least one light-emitting functional layer 4 is located within the at least one isolation opening K, so that light emitted from the at least one light-emitting functional layer 4 can exit through the at least one isolation opening K. The orthographic projection of the at least one isolation opening K on the substrate 1 includes the at least one first edge B1 and the at least one second edge B2, and the length of the first edge B1 is greater than the length of the second edge B2. In this embodiment, the unit length connecting area of the first sub-portion Z1 of the first electrode 3 connecting with the inner wall surface of the isolation structure 2 is compared with the unit length connecting area of the second sub-portion Z2 of the first electrode 3 connecting with the inner wall surface of the isolation structure 2, so as to accurately determine the connecting effect. The first unit length area being greater than the second unit length area indicates that the connecting effect of the first sub-portion Z1 on the inner wall surface of the isolation structure 2 corresponding to the first edge B1 is better, which can reduce the impedance between the first electrode 3 and the isolation structure 2, thereby improving the performance of the display panel 10.

In some optional embodiments, within the same isolation opening K, the first edge B1 and the second edge B2 are parallel to each other. Considering factors such as manufacturing cost and difficulty, by using the portion of the isolation structure 2 corresponding to the first edge B1 and second edge B2 that are parallel, effective connection of the first electrode 3 is achieved. Under a condition that the first edge B1 and the second edge B2 are parallel, the orthographic projection of the corresponding isolation opening K on the substrate 1 may have a shape such as a trapezoid shape or a hexagon shape.

Optionally, within the same isolation opening K, along a direction perpendicular to the extension direction of the first edge B1, the first edge B1 and the second edge B2 are at least partially oppositely arranged, to improve the regularity of the arrangement of the isolation opening K and facilitate subsequent evaporation of the first electrode 3.

In some optional embodiments, the first edge B1 is the longest edge among the edges of the orthographic projection of the at least one isolation opening K on the substrate 1. The lengths of other edges of the orthographic projection of the at least one isolation opening K on the substrate 1 are all less than the length of the first edge B1, i.e., the first distance P1 corresponding to the first sub-portion Z1 is greater than the distances of other portions of the first electrode 3 from the isolation structure 2.

Referring to FIGS. 1 to 4, yet another embodiment of the application provides a display panel 10, including: a substrate 1; an isolation structure 2 disposed on a side of the substrate 1, the isolation structure 2 being provided with at least one isolation opening K, an orthographic projection of the at least one isolation opening K on the substrate 1 including at least one first edge B1 and at least one second edge B2, a length of the first edge B1 being greater than a length of the second edge B2; at least one light-emitting functional layer 4, at least a portion of the at least one light-emitting functional layer 4 being located within the at least one isolation opening K; at least one first electrode 3, the at least one first electrode 3 being located on a side of the at least one light-emitting functional layer 4 away from the substrate 1 and connecting with the isolation structure 2, the at least one first electrode 3 including at least one first sub-portion Z1 and at least one second sub-portion Z2, the first sub-portion Z1 being a portion of the first electrode 3 connecting with the isolation structure 2 corresponding to the first edge B1, the second sub-portion Z2 being a portion of the first electrode 3 connecting with the isolation structure 2 corresponding to the second edge B2; wherein within the same first electrode 3, a maximum thickness of the first sub-portion Z1 is greater than a maximum thickness of the second sub-portion Z2.

In this embodiment, the maximum thickness H1 of the first sub-portion Z1 and the maximum thickness H2 of the second sub-portion Z2 may refer to the maximum thicknesses of the first sub-portion Z1 and the second sub-portion Z2 along their respective extension directions. Alternatively, exemplarily, the maximum thickness H1 of the first sub-portion Z1 and the maximum thickness H2 of the second sub-portion Z2 may be the maximum thicknesses of the first sub-portion Z1 and the second sub-portion Z2 in the thickness direction of the display panel, or may be the maximum thicknesses of the first sub-portion Z1 and the second sub-portion Z2 in a direction perpendicular to the inner wall surface of the isolation structure 2 connecting the first sub-portion Z1 and the second sub-portion Z2.

By increasing the maximum thickness H1 of the first sub-portion Z1, the resistance of the first sub-portion Z1 can be reduced, the connecting impedance between the first sub-portion Z1 and the isolation structure 2 can be improved, and the first distance P1 can be correspondingly increased, allowing the connecting area of the first sub-portion Z1 to be maximized, sacrificing the connecting effect of other edges to achieve overall maximization of the cathode connecting effect, and improving the display effect of the display panel.

In some optional embodiments, within the same isolation opening K, the first edge B1 and the second edge B2 are parallel to each other. Considering factors such as manufacturing cost and difficulty, by using the portion of the isolation structure 2 corresponding to the first edge B1 and second edge B2 that are parallel, effective connection of the first electrode 3 is achieved. Under a condition that the first edge B1 and the second edge B2 are parallel, the orthographic projection of the corresponding isolation opening K on the substrate 1 may have a shape such as a trapezoid shape or a hexagon shape.

Optionally, within the same isolation opening K, along a direction perpendicular to the extension direction of the first edge B1, the first edge B1 and the second edge B2 are at least partially oppositely arranged, to improve the regularity of the arrangement of the isolation opening K and facilitate subsequent evaporation of the first electrode 3.

In some optional embodiments, the first edge B1 is the longest edge among the edges of the orthographic projection of the at least one isolation opening K on the substrate 1. The lengths of other edges of the orthographic projection of the at least one isolation opening K on the substrate 1 are all less than the length of the first edge B1, i.e., the first distance P1 corresponding to the first sub-portion Z1 is greater than the distances of other portions of the first electrode 3 from the isolation structure 2.

Referring to FIGS. 1 to 4, yet another embodiment of the application provides a display panel 10, including: a substrate 1; an isolation structure 2 disposed on a side of the substrate 1, the isolation structure 2 being provided with at least one isolation opening K, an orthographic projection of the at least one isolation opening K on the substrate 1 including at least one first edge B1 and at least one second edge B2, a length of the first edge B1 being greater than a length of the second edge B2; at least one light-emitting functional layer 4, at least a portion of the at least one light-emitting functional layer 4 being located within the at least one isolation opening K; at least one first electrode 3, the at least one first electrode 3 being located on a side of the at least one light-emitting functional layer 4 away from the substrate 1 and connecting with the isolation structure 2, the at least one first electrode 3 including at least one first sub-portion Z1 and at least one second sub-portion Z2, the first sub-portion Z1 being a portion of the first electrode 3 connecting with the isolation structure 2 corresponding to the first edge B1, the second sub-portion Z2 being a portion of the first electrode 3 connecting with the isolation structure 2 corresponding to the second edge B2; wherein within the same first electrode 3, in a cross-section along the thickness direction of the display panel 10, a contact length between the first sub-portion Z1 of the first electrode 3 and an inner wall surface of the isolation structure 2 is a first contact length J1, a contact length between the second sub-portion Z2 of the first electrode 3 and the inner wall surface of the isolation structure 2 is a second contact length J2; wherein the first contact length J1 is greater than the second contact length J2, and the inner wall surface of the isolation structure 2 is a surface of the isolation structure 2 facing the isolation opening K.

The display panel 10 provided by the embodiment of the application includes the substrate 1, the isolation structure 2, and the at least one first electrode 3. At least a portion of the at least one light-emitting functional layer 4 is located within the at least one isolation opening K, so that light emitted from the at least one light-emitting functional layer 4 can exit through the at least one isolation opening K. The orthographic projection of the at least one isolation opening K on the substrate 1 includes the at least one first edge B1 and the at least one second edge B2, and the length of the first edge B1 is greater than the length of the second edge B2. The cross-section along the thickness direction of the display panel 10 may include a first plane and a second plane. Optionally, the first plane is perpendicular to the extension direction of the first edge B1, and the second plane is perpendicular to the extension direction of the second edge B2. The first contact length J1 is the contact length between the first sub-portion Z1 of the first electrode 3 and the inner wall surface of the isolation structure 2 on the first plane, and the second contact length J2 is the contact length between the second sub-portion Z2 of the first electrode 3 and the inner wall surface of the isolation structure 2 on the second plane. Through research and experimentation, the inventors have found that the first contact length J1 being greater than the second contact length J2 indicates that the connecting effect between the first sub-portion Z1 and the inner wall surface of the isolation structure 2 is better than the connecting effect between the second sub-portion Z2 and the inner wall surface of the isolation structure 2, which can reduce the impedance between the first electrode 3 and the isolation structure 2, thereby improving the performance of the display panel 10.

In some optional embodiments, within the same isolation opening K, the first edge B1 and the second edge B2 are parallel to each other. Considering factors such as manufacturing cost and difficulty, by using the portion of the isolation structure 2 corresponding to the first edge B1 and second edge B2 that are parallel, effective connection of the first electrode 3 is achieved. Under a condition that the first edge B1 and the second edge B2 are parallel, the orthographic projection of the corresponding isolation opening K on the substrate 1 may have a shape such as a trapezoid shape or a hexagon shape.

Optionally, within the same isolation opening K, along a direction perpendicular to the extension direction of the first edge B1, the first edge B1 and the second edge B2 are at least partially oppositely arranged, to improve the regularity of the arrangement of the isolation opening K and facilitate subsequent evaporation of the first electrode 3.

In some optional embodiments, the first edge B1 is the longest edge among the edges of the orthographic projection of the at least one isolation opening K on the substrate 1. The lengths of other edges of the orthographic projection of the at least one isolation opening K on the substrate 1 are all less than the length of the first edge B1, i.e., the first distance P1 corresponding to the first sub-portion Z1 is greater than the distances of other portions of the first electrode 3 from the isolation structure 2.

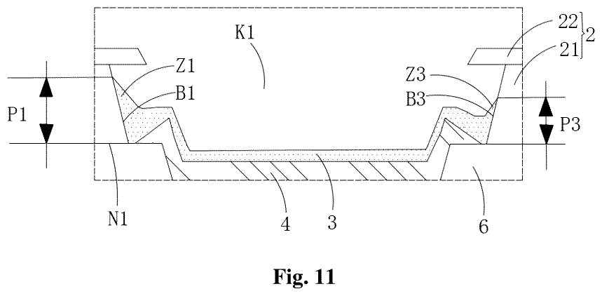

Referring to FIGS. 10 to 11, yet another embodiment of the application provides a display panel 10, including: a substrate 1; an isolation structure 2 disposed on a side of the substrate 1, the isolation structure 2 being provided with at least one isolation opening K, an orthographic projection of the at least one isolation opening K on the substrate 1 including at least one first edge B1 and at least one third edge B3, an extension direction of the first edge B1 intersecting with an extension direction of the third edge B3, and a length of the first edge B1 being greater than a length of the third edge B3; at least one light-emitting functional layer 4, at least a portion of the at least one light-emitting functional layer 4 being located within the at least one isolation opening K; at least one first electrode 3, the at least one first electrode 3 being located on a side of the at least one light-emitting functional layer 4 away from the substrate 1 and connecting with the isolation structure 2, the at least one first electrode 3 including at least one first sub-portion Z1 and at least one third sub-portion Z3, the first sub-portion Z1 being a portion of the first electrode 3 connecting with the isolation structure 2 corresponding to the first edge B1, the third sub-portion Z3 being a portion of the first electrode 3 connecting with the isolation structure 2 corresponding to the third edge B3; wherein the isolation structure 2 includes a first surface N1 close to the substrate 1, within the same first electrode 3, and in a thickness direction of the display panel 10, a distance between an end of the first sub-portion Z1 away from the substrate 1 and a plane where the first surface N1 lies is a first distance P1, a distance between an end of the third sub-portion Z3 away from the substrate 1 and the plane where the first surface N1 lies is a third distance P3, and the first distance P1 is greater than the third distance P3.

The display panel 10 provided by the embodiment of the application includes the substrate 1, the isolation structure 2, and the at least one first electrode 3. At least a portion of the at least one light-emitting functional layer 4 is located within the at least one isolation opening K, so that light emitted from the at least one light-emitting functional layer 4 can exit through the at least one isolation opening K. The length of the first edge B1 is greater than the length of the third edge B3. This embodiment correspondingly defines that the first distance P1 of the first sub-portion Z1 corresponding to the first edge B1 is greater than the third distance P3 of the third sub-portion Z3 corresponding to the third edge B3, thereby further increasing the connecting area between the first sub-portion Z1 and the isolation structure 2 corresponding to the first edge B1. The larger the connecting area, the smaller the impedance between the corresponding first sub-portion Z1 and the isolation structure 2 corresponding to the first edge B1, thereby improving the display effect of the display panel 10, reducing the incidence of dark spots or dark patches, and enhancing the reliability of the display panel 10.

In some optional embodiments, the orthographic projection of the at least one isolation opening K on the substrate 1 further includes at least one second edge B2, and the length of the first edge B1 is equal to the length of the second edge B2.

In some optional embodiments, within the same isolation opening K, the first edge B1 and the second edge B2 are parallel to each other, and the extension direction of the first edge B1 intersects with the extension direction of the third edge B3. Considering factors such as manufacturing cost and difficulty, by using the portion of the isolation structure 2 corresponding to the first edge B1 and the second edge B2 that are parallel, effective connection of the first electrode 3 is achieved. Under a condition that the first edge B1 and the second edge B2 are parallel, the orthographic projection of the corresponding isolation opening K on the substrate 1 may have a shape such as a rectangle shape, a rhombus shape, a parallelogram shape, a trapezoid shape, or a hexagon shape.

In some optional embodiments, the orthographic projection of the at least one isolation opening K on the substrate 1 further includes at least one fourth edge B4, the first edge B1 and the second edge B2 are opposite and parallel to each other, and the third edge B3 and the fourth edge B4 are opposite and parallel to each other.

In this embodiment, the orthographic projection of the at least one isolation opening K on the substrate 1 has four edges and may correspond to a shape such as a rectangle shape, a parallelogram shape, or a rhombus shape.

In some optional embodiments, the at least one first electrode 3 further includes at least one second sub-portion Z2, the second sub-portion Z2 being a portion of the first electrode 3 connecting with the isolation structure 2 corresponding to the second edge B2; in the thickness direction of the display panel 10, a distance between an end of the second sub-portion Z2 away from the substrate 1 and the plane where the first surface N1 lies is a second distance P2, and the first distance P1 is greater than or equal to the second distance P2.

In this embodiment, the length of the first edge B1 is equal to the length of the second edge B2, and correspondingly, the first distance P1 may be greater than the second distance P2, so as to increase the connecting area between the first sub-portion Z1 and the isolation structure 2 corresponding to the first edge B1, reduce the impedance between the corresponding first sub-portion Z1 and the isolation structure 2 corresponding to the first edge B1, thereby improving the display effect of the display panel 10, reducing the incidence of dark spots or dark patches, and enhancing the reliability of the display panel 10.

Alternatively, since the length of the first edge B1 is equal to the length of the second edge B2, and the first edge B1 and the second edge B2 both are long edges, the first distance P1 may also be equal to the second distance P2. Correspondingly, when manufacturing the first sub-portion Z1 and the second sub-portion Z2, it is not necessary to adjust the evaporation angle, thereby reducing manufacturing difficulty.

In some optional embodiments, the second distance P2 is greater than the third distance P3. Under a condition that the first edge B1 and the second edge B2 are parallel, the first edge B1 and the second edge B2 can be effective connecting edges for the first sub-portion Z1 and the second sub-portion Z2 formed by a linear evaporation source. Since the length of the third edge B3 is less than the lengths of the second edge B2 and the first edge B1, its impact on the connecting effect is limited. By setting the third distance P3 less than the second distance P2, the connecting area of the first sub-portion Z1 can be maximized, sacrificing the connecting effect of other edges to achieve overall maximization of the cathode connecting effect, thereby improving the display effect of the display panel.

In some optional embodiments, within the same first electrode 3, in a cross-section along the thickness direction of the display panel 10, a contact length between the first sub-portion Z1 of the first electrode 3 and the inner wall surface of the isolation structure 2 is a first contact length J1, a contact length between the third sub-portion Z3 of the first electrode 3 and the inner wall surface of the isolation structure 2 is a third contact length J3; wherein the first contact length J1 is greater than the third contact length J3, and the inner wall surface of the isolation structure 2 is a surface of the isolation structure 2 facing the isolation opening K.

The cross-section along the thickness direction of the display panel 10 may include a first plane and a third plane. Optionally, the first plane is perpendicular to the extension direction of the first edge B1, and the third plane is perpendicular to the extension direction of the third edge B3. The first contact length J1 is the contact length between the first sub-portion Z1 of the first electrode 3 and the inner wall surface of the isolation structure 2 on the first plane, and the third contact length J3 is the contact length between the third sub-portion Z3 of the first electrode 3 and the inner wall surface of the isolation structure 2 on the third plane.

Through research and experimentation, the inventors have found that the first contact length J1 being greater than the third contact length J3 indicates that the connecting effect between the first sub-portion Z1 and the inner wall surface of the isolation structure 2 is better than the connecting effect between the third sub-portion Z3 and the inner wall surface of the isolation structure 2.

In some optional embodiments, within the same first electrode 3, a unit length connecting area of the first sub-portion Z1 of the first electrode 3 connecting with the isolation structure 2 is a first unit length area, a unit length connecting area of the third sub-portion Z3 of the first electrode 3 connecting with the isolation structure 2 is a third unit length area, and the first unit length area is greater than the third unit length area; wherein the first unit length area is a ratio of a total area of the first sub-portion Z1 of the first electrode 3 connecting with the isolation structure 2 to the length of the first edge B1, and the third unit length area is a ratio of a total area of the third sub-portion Z3 of the first electrode 3 connecting with the isolation structure 2 to the length of the third edge B3.

Considering that the lengths of the first edge B1 and the third edge B3 are different, in this embodiment, the unit length connecting area of the first sub-portion Z1 of the first electrode 3 connecting with the inner wall surface of the isolation structure 2 is compared with the unit length connecting area of the third sub-portion Z3 of the first electrode 3 connecting with the inner wall surface of the isolation structure 2, so as to accurately determine the connecting effect. The first unit length area being greater than the third unit length area indicates that the connecting effect of the first sub-portion Z1 on the inner wall surface of the isolation structure 2 corresponding to the first edge B1 is better, which can reduce the impedance between the first electrode 3 and the isolation structure 2, thereby improving the performance of the display panel 10.

An embodiment of the application further provides a display device, including the display panel 10 according to any of the above embodiments.

The display device provided by the embodiment of the application has the effects of the display panel 10 in any of the above embodiments. The same or corresponding structures and explanations of terms are not repeated here.

The display panel 10 provided by the embodiments of the application may be an Organic Light-Emitting Diode (OLED) display panel 10, a Quantum Dot Light Emitting Diode (QLED) display panel 10, or a micro planar display panel 10 (Micro-OLED or Micro-LED), etc.

The display device in the embodiments of the application includes but is not limited to devices with display functions such as mobile phones, Personal Digital Assistants (PDAs), tablet computers, e-books, televisions, access control systems, smart fixed-line telephones, and control panels.

The above are only specific embodiments of the application. Those skilled in the art can clearly understand that for the convenience and brevity of description, the specific working processes of the described systems, modules, and units can refer to the corresponding processes in the foregoing method embodiments and will not be repeated here. It should be understood that the protection scope of the application is not limited thereto. Any person skilled in the art can easily think of various equivalent modifications or substitutions within the scope disclosed in the application, and these modifications or substitutions should be covered within the protection scope of the application.

Furthermore, the exemplary embodiments mentioned in the application describe some methods or systems based on a series of steps or devices. However, the application is not limited to the order of the above steps. That is, the steps can be performed in the order mentioned in the embodiments, in an order different from the embodiments, or several steps can be performed simultaneously.

What is claimed is:

1. A display panel, comprising:
a substrate;
an isolation structure disposed on a side of the substrate, the isolation structure being provided with at least one isolation opening, an orthographic projection of the at least one isolation opening on the substrate comprising at least one first edge and at least one second edge, within the same isolation opening, a length of the first edge being greater than a length of the second edge;
at least one light-emitting functional layer, at least a portion of the at least one light-emitting functional layer being located within the at least one isolation opening;
at least one first electrode, the at least one first electrode being located on a side of the at least one light-emitting functional layer away from the substrate and connecting with the isolation structure, the at least one first electrode comprising at least one first sub-portion and at least one second sub-portion, the first sub-portion being a portion of the first electrode connecting with the isolation structure corresponding to the first edge, the second sub-portion being a portion of the first electrode connecting with the isolation structure corresponding to the second edge;
wherein the isolation structure comprises a first surface close to the substrate, within the same first electrode, and in a thickness direction of the display panel, a distance between an end of the first sub-portion away from the substrate and a plane where the first surface lies is a first distance, a distance between an end of the second sub-portion away from the substrate and the plane where the first surface lies is a second distance, and the first distance is greater than the second distance.

2. The display panel according to claim 1, wherein within the same isolation opening, an angle between an extension direction of the first edge and an extension direction of the second edge is greater than or equal to 0° and less than or equal to 10°;
the first edge and the second edge are both straight edges, or, at least one of the first edge and the second edge is a curved edge.

3. The display panel according to claim 1, wherein,
the orthographic projection of the at least one isolation opening on the substrate further comprises at least one third edge, within the same isolation opening, an extension direction of the third edge intersects with the extension direction of the first edge, and a length of the third edge is less than the length of the first edge;
the at least one first electrode further comprises at least one third sub-portion, the third sub-portion is a portion of the first electrode connecting with the isolation structure corresponding to the third edge;
in the thickness direction of the display panel, a distance between an end of the third sub-portion away from the substrate and the plane where the first surface lies is a third distance, and the third distance is less than the first distance.

4. The display panel according to claim 3, wherein within the same first electrode, in a cross-section along the thickness direction of the display panel, a contact length between the first sub-portion of the first electrode and an inner wall surface of the isolation structure is a first contact length, a contact length between the third sub-portion of the first electrode and the inner wall surface of the isolation structure is a third contact length, wherein the first contact length is greater than the third contact length, and the inner wall surface of the isolation structure is a surface of the isolation structure facing the isolation opening.

5. The display panel according to claim 3, wherein within the same first electrode, a unit length connecting area of the first sub-portion of the first electrode connecting with the isolation structure is a first unit length area, a unit length connecting area of the third sub-portion of the first electrode connecting with the isolation structure is a third unit length area, the first unit length area is greater than the third unit length area, wherein the first unit length area is a ratio of a total area of the first sub-portion of the first electrode connecting with the isolation structure to the length of the first edge, and the third unit length area is a ratio of a total area of the third sub-portion of the first electrode connecting with the isolation structure to the length of the third edge.

6. The display panel according to claim 3, wherein within the same first electrode, in a cross-section along the thickness direction of the display panel, a contact length between the second sub-portion of the first electrode and an inner wall surface of the isolation structure is a second contact length, a contact length between the third sub-portion of the first electrode and the inner wall surface of the isolation structure is a third contact length, wherein the second contact length is greater than the third contact length, and the inner wall surface of the isolation structure is a surface of the isolation structure facing the isolation opening.

7. The display panel according to claim 3, wherein within the same first electrode, a unit length connecting area of the second sub-portion of the first electrode connecting with the isolation structure is a second unit length area, a unit length connecting area of the third sub-portion of the first electrode connecting with the isolation structure is a third unit length area, the second unit length area is greater than the third unit length area, wherein the second unit length area is a ratio of a total area of the second sub-portion of the first electrode connecting with the isolation structure to the length of the second edge, and the third unit length area is a ratio of a total area of the third sub-portion of the first electrode connecting with the isolation structure to the length of the third edge.

8. The display panel according to claim 3, wherein within the same isolation opening, the first edge and the second edge are opposite and parallel to each other;
the orthographic projection of the at least one isolation opening on the substrate further comprises at least one fourth edge, within the same isolation opening, an extension direction of the fourth edge intersects with the extension direction of the first edge, a length of the fourth edge is less than the length of the first edge, and the fourth edge and the third edge are oppositely arranged;
the at least one first electrode further comprises at least one fourth sub-portion, the fourth sub-portion is a portion of the first electrode connecting with the isolation structure corresponding to the fourth edge;
in the thickness direction of the display panel, a distance between an end of the fourth sub-portion away from the substrate and the plane where the first surface lies is a fourth distance, and the fourth distance is less than the first distance.

9. The display panel according to claim 8, wherein within the same first electrode, in a cross-section along the thickness direction of the display panel, a contact length between the second sub-portion of the first electrode and an inner wall surface of the isolation structure is a second contact length, a contact length between the fourth sub-portion of the first electrode and the inner wall surface of the isolation structure is a fourth contact length, wherein the second contact length is greater than the fourth contact length, and the inner wall surface of the isolation structure is a surface of the isolation structure facing the isolation opening.

10. The display panel according to claim 8, wherein within the same first electrode, a unit length connecting area of the second sub-portion of the first electrode connecting with the isolation structure is a second unit length area, a unit length connecting area of the fourth sub-portion of the first electrode connecting with the isolation structure is a fourth unit length area, the second unit length area is greater than the fourth unit length area, wherein the second unit length area is a ratio of a total area of the second sub-portion of the first electrode connecting with the isolation structure to the length of the second edge, and the fourth unit length area is a ratio of a total area of the fourth sub-portion of the first electrode connecting with the isolation structure to the length of the fourth edge.

11. The display panel according to claim 1, wherein the display panel further comprises a conductive layer disposed between the substrate and the isolation structure;
the conductive layer comprises a data signal line extending along a first direction,
an extension direction of the at least one first edge is parallel to the first direction;
within the same first electrode, a maximum thickness of the first sub-portion is greater than a maximum thickness of the second sub-portion; or,
within the same first electrode, an average thickness of the first sub-portion is greater than an average thickness of the second sub-portion.

12. The display panel according to claim 1, wherein within the same first electrode, in a cross-section along the thickness direction of the display panel, a contact length between the first sub-portion of the first electrode and an inner wall surface of the isolation structure is a first contact length, a contact length between the second sub-portion of the first electrode and the inner wall surface of the isolation structure is a second contact length;
wherein the first contact length is greater than the second contact length, and the inner wall surface of the isolation structure is a surface of the isolation structure facing the isolation opening.

13. The display panel according to claim 1, wherein within the same first electrode, a unit length connecting area of the first sub-portion of the first electrode connecting with the isolation structure is a first unit length area, a unit length connecting area of the second sub-portion of the first electrode connecting with the isolation structure is a second unit length area, the first unit length area is greater than the second unit length area;
wherein the first unit length area is a ratio of a total area of the first sub-portion of the first electrode connecting with the isolation structure to the length of the first edge, and the second unit length area is a ratio of a total area of the second sub-portion of the first electrode connecting with the isolation structure to the length of the second edge.

14. The display panel according to claim 1, wherein in a direction away from the substrate, the isolation structure comprises a first sub-layer and a second sub-layer stacked sequentially, the at least one first sub-portion of the at least one first electrode connects with the first sub-layer; an orthographic projection of the first sub-layer on the substrate is located within an orthographic projection of the second sub-layer on the substrate.

15. The display panel according to claim 1, wherein the at least one light-emitting functional layer comprises a plurality of light-emitting functional layers, the plurality of light-emitting functional layers comprise a first light-emitting unit, a second light-emitting unit, and a third light-emitting unit, the first light-emitting unit is configured to emit light of a first color, the second light-emitting unit is configured to emit light of a second color, and the third light-emitting unit is configured to emit light of a third color;
the at least one isolation opening comprises a plurality of isolation openings, the plurality of isolation openings comprise a first isolation opening, a second isolation opening, and a third isolation opening, at least a portion of the first light-emitting unit is located within the first isolation opening, at least a portion of the second light-emitting unit is located within the second isolation opening, and at least a portion of the third light-emitting unit is located within the third isolation opening.

16. The display panel according to claim 15, wherein an area of an orthographic projection of the first isolation opening on the substrate is less than an area of an orthographic projection of the second isolation opening on the substrate, and the area of the orthographic projection of the first isolation opening on the substrate is less than an area of an orthographic projection of the third isolation opening on the substrate;
the at least one first edge comprises a plurality of first edges, the plurality of first edges comprise a first edge of the first isolation opening, a first edge of the second isolation opening, and the first edge of the third isolation opening;
the first edge of the first isolation opening, the first edge of the second isolation opening, and the first edge of the third isolation opening are mutually parallel to each other.

17. The display panel according to claim 16, wherein a length of the first edge of the first isolation opening, a length of the first edge of the second isolation opening, and a length of the first edge of the third isolation opening are all equal;
the at least one first sub-portion comprises a plurality of first sub-portions, the plurality of first sub-portions comprise a first sub-portion located within the first isolation opening, a first sub-portion located within the second isolation opening, and a first sub-portion located within the third isolation opening, the first distance of the first sub-portion located within the first isolation opening, the first distance of the first sub-portion located within the second isolation opening, and the first distance of the first sub-portion located within the third isolation opening are all equal.

18. A display panel, comprising:
a substrate;
an isolation structure disposed on a side of the substrate, the isolation structure being provided with at least one isolation opening, an orthographic projection of the at least one isolation opening on the substrate comprising at least one first edge and at least one second edge, within the same isolation opening, a length of the first edge being greater than a length of the second edge,
at least one light-emitting functional layer, at least a portion of the at least one light-emitting functional layer being located within the at least one isolation opening;
at least one first electrode, the at least one first electrode being located on a side of the at least one light-emitting functional layer away from the substrate and connecting with the isolation structure, the at least one first electrode comprising at least one first sub-portion and at least one second sub-portion, the first sub-portion being a portion of the first electrode connecting with the isolation structure corresponding to the first edge, the second sub-portion being a portion of the first electrode connecting with the isolation structure corresponding to the second edge;
wherein within the same first electrode, a unit length connecting area of the first sub-portion of the first electrode connecting with the isolation structure is a first unit length area, a unit length connecting area of the second sub-portion of the first electrode connecting with the isolation structure is a second unit length area, the first unit length area is greater than the second unit length area; wherein the first unit length area is a ratio of a total area of the first sub-portion of the first electrode connecting with the isolation structure to the length of the first edge, and the second unit length area is a ratio of a total area of the second sub-portion of the first electrode connecting with the isolation structure to the length of the second edge.

19. The display panel according to claim 18, wherein within the same isolation opening, the first edge and the second edge are parallel to each other;
or, within the same isolation opening, along a direction perpendicular to an extension direction of the first edge, the first edge and the second edge are at least partially oppositely arranged;
the first edge is a longest edge among edges of the orthographic projection of the at least one isolation opening on the substrate.

20. A display device, comprising the display panel according to the claim 1.
